(19) United States
(12) Patent Application Publication
(10) Pub. No.: US 2023/0130197 A1
(43) Pub. Date: Apr. 27, 2023

(54) FILTER COEFFICIENT UPDATING DEVICE, FILTER DEVICE, DEMODULATING DEVICE, RECEIVING DEVICE,TRANSMITTING AND RECEIVING SYSTEM, FILTER COEFFICIENT UPDATING METHOD, AND RECORDINGMEDIUM

(71) Applicant: NEC Corporation, Minato-ku, Tokyo (JP)

(72) Inventor: Manabu ARIKAWA, Tokyo (JP)

(73) Assignee: NEC Corporation, Minato-ku, Tokyo (JP)

(21) Appl. No.: 17/918,179

(22) PCT Filed: Feb. 15, 2021
(86) PCT No.: PCT/JP2021/005521

§ 371 Date: Oct. 11, 2022

(30) Foreign Application Priority Data
Apr. 14, 2020 (JP) 2020-072420

(51) Int. Cl. H04B 10/61

(52) U.S. Cl. CPC H04B 10/616; H04B 10/6166

(57) ABSTRACT

In order to reduce the amount of calculation for signal distortion compensation, this filter coefficient updating device for updating the filter coefficients of a plurality of filters in a filter layer comprising the plurality of filters, which are connected in a first plurality of stages with respect to received data, is provided with: a deriving unit for deriving the respective filter coefficients of the plurality of filters in one or a plurality of stages included in the first plurality of stages, by means of output data output from the last stage of the first plurality of stages; and an updating unit for updating each of the filter coefficients.

### TECHNICAL FIELD

The present invention relates to a filter for signal processing and derivation of a filter coefficient.

### BACKGROUND ART

In optical fiber communication, a multilevel modulation scheme such as a QAM scheme is generally employed in order to achieve high utilization efficiency of a signal spectrum. Herein, QAM is an abbreviation for quadrature amplitude modulation. Since introduction of a coherent reception technique, flexible equalization processing on a received signal can be performed by digital signal processing. However, optical transmission using a multilevel modulation signal is generally vulnerable to a distortion (hereinafter, also referred to as a “signal distortion”) occurring in a signal. Thus, processing of compensating for influence of a signal distortion needs to be performed on received data.

FIG. 1 is a conceptual diagram illustrating a configuration of an optical communication system 100 being an example of a general optical communication system that performs optical transmission using a QAM scheme signal. The optical communication system 100 includes an optical transmitter 110, a transmission path 120, and an optical receiver 130.

The optical transmitter 110 includes an encoding unit 111, an LD 112, and an optical modulator 113. Herein, LD is an abbreviation for laser diode.

The encoding unit 111 encodes input data, and inputs the encoded data to the optical modulator 113. The encoded data are divided into, for example, four series, and are input to the optical modulator 113 in parallel.

The encoding unit 111 generates four series of signals in total, including quadrature phase amplitudes I and Q for each of an X-polarized wave and a Y-polarized wave orthogonal thereto. Herein, I is an abbreviation for in-phase. Q is an abbreviation for quadrature.

The LD 112 inputs laser light being CW light to the optical modulator 113. Herein, CW is an abbreviation for continuous wave.

The optical modulator 113 modulates CW light being input from the LD 112 by using data after encoding input from the encoding unit 111. A modulated optical signal is transmitted toward the optical receiver 130 via the transmission path 120.

The transmission path 120 transmits an optical signal being input from the optical transmitter 110 to the optical receiver 130. The transmission path 120 is, for example, an optical transmission path including an optical fiber, an EDFA, and the like. Herein, EDFA is an abbreviation for erbium doped optical fiber amplifier.

The optical receiver 130 includes an LD 131, a coherent receiver 132, an ADC 133, a demodulating unit 134, and a decoding unit 135. Herein, ADC is an abbreviation for analog-to-digital converter.

The LD 131 inputs LD light to the coherent receiver 132 as a so-called local oscillator.

The coherent receiver 132 is, for example, a polarization diversity type coherent receiver. The coherent receiver 132 detects an optical signal sent from the optical transmitter 110 via the transmission path 120 by using laser light being input from the LD 131, and inputs four series of received signals associated with quadrature phase amplitudes for each polarized wave, to the ADC 133.

The ADC 133 converts, by sampling, input four series of analog signals into received data being digital four series of received sample values, and inputs the received data to the demodulating unit 134.

The demodulating unit 134 performs data processing for demodulation in a digital region of input four series of received data. When performing demodulation, the demodulating unit 134 performs compensation processing to be described later. The demodulating unit 134 inputs four series of received data after demodulation and compensation processing, to the decoding unit 135.

The decoding unit 135 decodes input four series of received data after demodulation, in association with encoding performed by the encoding unit 111. Consequently, the decoding unit 135 restores data equivalent to data being input to the optical transmitter 110 from received data transmitted by the optical transmitter 110, and outputs the restored data.

The demodulating unit 134 and the decoding unit 135 are constituted of a computer or a processor as a hardware configuration. In addition, processing performed by the demodulating unit 134 and the decoding unit 135 is executed typically by a program or information.

FIG. 2 is a conceptual diagram illustrating a processing example of compensation processing to be performed for demodulation of received data in the demodulating unit 134 of the optical receiver 130 in FIG. 1.

The demodulating unit 134 sequentially performs wavelength dispersion compensation processing 201, polarization fluctuation compensation processing 202, and carrier phase compensation processing 203 on input four series of received data.

These pieces of compensation processing are processing of compensating for signal distortions for each cause of a signal distortion. The wavelength dispersion compensation processing 201 is processing of compensating for a signal distortion caused by a wavelength dispersion generated during optical fiber transmission. The polarization fluctuation compensation processing 202 is processing of compensating for a signal distortion caused by a polarization state fluctuation and a polarization mode dispersion being generated during optical fiber transmission. The carrier phase compensation processing 203 is processing of compensating for a signal distortion caused by a frequency offset and a phase offset between a carrier of a transmitting optical signal and receiving-side local oscillator light.

The compensation processing in FIG. 2 is performed on four series of received data to be input to the demodulating unit 134 from the ADC 133 in FIG. 1.

The wavelength dispersion compensation processing 201 and the carrier phase compensation processing 203 are performed on two series of received data of IQ components for each polarized wave. Meanwhile, the polarization fluctuation compensation processing 202 (sometimes called polarization separation processing) is performed on four series of received data for both polarized waves.

FIG. 3 is a conceptual diagram illustrating general MIMO signal processing having a 2×2 configuration in which the polarization fluctuation compensation processing 202 in FIG. 2 is performed. Herein, a (first number)×(second number) configuration represents a configuration in which filters are arranged in a matrix of (first number)×(second number). MIMO is an abbreviation for multiple-input and multiple-output. In the signal processing, each series of received data for each polarized wave is converted into complex data including an I component and a Q component. Then, filter processing using a filter having a 2×2 configuration is performed on each series of the complex data. In an example in FIG. 3, filter processing (finite impulse response (FIR) processing) using an FIR filter is used for the filter processing.

Unlike the wavelength dispersion, the polarization state fluctuation during optical fiber transmission changes due to various causes such as temperature and bending. Thus, in a configuration in FIG. 3, a filter coefficient is updated by an adaptive equalization method in order to perform compensation processing capable of following changes due to various causes. At that time, for example, CMA or DDLMS disclosed in NPL 1 can be used as an algorithm for filter coefficient update. Herein, CMA is an abbreviation for constant modulus algorithm. DDLMS is an abbreviation for decision directed least mean square.

A detail of the processing in FIG. 3 is described in, for example, Japanese Patent Application No. 2019-191623.

Causes of signal distortions occurring in optical fiber communication include, besides the wavelength dispersion and the polarization state fluctuation, a time skew (hereinafter, also referred to as an “IQ skew”) between an I component and a Q component of a received signal occurring in a transmitter or a receiver. The IQ skew cannot be compensated for by MIMO filter processing on a complex signal as illustrated in FIG. 3. Further, the IQ skew often has an amount of IQ skew that is not known accurately. Thus, it is desirable that the IQ skew be adaptively subjected to compensation processing. In order to compensate for such an IQ skew, it is effective to perform real MIMO signal processing of independently processing each of an I component and a Q component as illustrated in FIG. 4, as disclosed in NPL 2.

Alternatively, in order to compensate for such an IQ skew, it is effective to perform MIMO signal processing as in FIG. 5, which is called widely linear (WL) filter processing, as disclosed in NPL 2.

The data processing (real 4×4 MIMO signal processing) illustrated in FIG. 4 is data processing using a filter having a 4×4 configuration with 16 real number coefficients. Meanwhile, the data processing (WL complex 4×2 MIMO signal processing) in FIG. 5 is for performing data processing using a filter having a 4×2×2 configuration with 16 real number coefficients as well. Accordingly, the configuration in FIG. 4 and the configuration in FIG. 5 are expressed differently but are equivalent. In the filter configurations in FIGS. 4 and 5, received data of an I component and received data of a Q component can be handled independently. Thus, in the filter configurations in FIGS. 4 and 5, it is possible to compensate for the IQ skew, an IQ imbalance, a frequency characteristic specific to an I component or a Q component, and the like.

The signal distortions attributable to the wavelength dispersion, the polarization fluctuation dispersion, the carrier phase, and the IQ skew described above are all linear distortions. Thus, it is also possible to compensate for the signal distortions collectively by using one MIMO filter.

However, in general optical fiber communication, compensation processing is performed on the signal distortions for each cause of a signal distortion, as in FIG. 2. The reason is that the signal distortions have different characteristics for each cause of each signal distortion.

For example, the signal distortion due to the wavelength dispersion can usually be handled as being static unless a transmission path is switched. In addition, the signal distortion due to the wavelength dispersion does not depend on a polarized wave and has a large temporal spread. Accordingly, a filter that compensates for the signal distortion due to the wavelength dispersion is a filter being fixed and independent of a polarized wave and having a large temporal spread.

Meanwhile, the polarization fluctuation fluctuates temporally, resulting in mixing between polarized waves. Thus, a filter that compensates for the signal distortion due to the polarization fluctuation needs to be a MIMO filter. In addition, in order to compensate for the signal distortion due to the polarization fluctuation, it is necessary to adaptively update a filter coefficient of the MIMO filter.

In view of the above, computational complexity can be reduced by utilizing a configuration of compensating for signal distortions for each cause of a signal distortion, rather than compensating for signal distortions due to all causes with one large-scale MIMO filter.

However, in order to compensate for signal distortions for each cause of a signal distortion, order of compensation for each cause of a signal distortion may be important. The order of compensation becomes a problem, for example, when IQ skew compensation processing is performed in a transmission path where the wavelength dispersion occurs.

The compensation processing for the signal distortions due to the wavelength dispersion, the polarization fluctuation, and the frequency/phase offset can all be represented by filter processing using a complex (MIMO) filter, and order of performing the pieces of compensation processing is interchangeable. In other words, the compensation processing of compensating for the distortions is achieved by a strictly linear (SL) (MIMO) filter, and there is no need to worry about the order of the compensation processing. However, the IQ skew and a WL (MIMO) filter that compensates therefor are generally not interchangeable with the filter processing of compensating for the signal distortions due to the wavelength dispersion, the polarization fluctuation, and the frequency/phase offset. Accordingly, in a case of compensating for signal distortions for each cause of a signal distortion including the IQ skew, the order of compensation processing for each cause of occurrence of a signal distortion is important. In an optical fiber communication system, signal distortions occur in order of an IQ skew (hereinafter, also referred to as a “Tx skew”) in a transmitter, a phenomenon (the wavelength dispersion and the polarization fluctuation) in an optical fiber, the frequency offset, and an IQ skew (hereinafter, also referred to as an “Rx skew”) in a receiver. As described above, the phenomenon in an optical fiber and the frequency offset are interchangeable when a non-linear effect in the optical fiber is ignored.

Therefore, in order to perform compensation processing for signal distortions due to the IQ skews in both a transmitter and a receiver, it is not enough just to change the MIMO filter to be used in the polarization fluctuation compensation processing 102 in FIG. 2 to that illustrated in FIG. 4 or 5.

Herein, NPL 2 discloses a method of compensating for the above-described signal distortions collectively with one MIMO filter. In addition, NPL 2 describes that it is possible to compensate for the signal distortions due to the IQ skews in both a transmitter and a receiver, by compensating for the wavelength dispersion, the polarization fluctuation, and the IQ skew with one WL MIMO filter, even in a transmission path with accumulated wavelength dispersion.

NPL 3 discloses a method of performing compensation processing for the above-described distortions for each cause of a signal distortion. NPL 3 describes that it is possible to compensate for the signal distortions due to the IQ skews in both a transmitter and a receiver, by performing wavelength dispersion compensation processing using a complex filter on each of I and Q components and thereafter performing filter processing using a complex MIMO filter having a 4×2 configuration.

### CITATION LIST

### Non Patent Literature

[NPL 1] S. Savory, “Digital filters for coherent optical receivers,” Opt. Express 16(2), 804 (2008).
[NPL 2] E. P. da Silva and D. Zibar, “Widely linear equalization for IQ imbalance and skew compensation in optical coherent receivers,” J. of Lightwave Technol. 34(15), 3577 (2016).
[NPL 3] R. Rios-Muller, et. al., “Blind receiver skew compensation and estimation for long-haul non-dispersion managed systems using adaptive equalizer,” J. of Lightwave Technol. 33(7), 1315 (2015).

### SUMMARY OF INVENTION

### Technical Problem

However, the method using one large-scale MIMO filter that is disclosed in NPL 2 increases computational complexity of a filter and requires many computational resources, as described above.

The method disclosed in NPL 3 performs compensation processing for each cause of a signal distortion, but needs a large-scale filter having a large temporal spread for wavelength dispersion compensation processing, for each of an I component and a Q component. Thus, the method disclosed in NPL 3 also increases computational complexity and requires many computational resources.

As described above, when compensation processing for the signal distortions due to the causes including the IQ skews in both a transmitter and a receiver is performed in a transmission path where the wavelength dispersion occurs, filter processing using a large-scale filter is needed. Thus, there is a problem that much computational complexity and many computational resources are required.

An object of the present invention is to provide a filter coefficient updating device and the like that reduce a calculation amount for signal distortion compensation.

### Solution to Problem

A filter coefficient updating device according to the present invention is a filter coefficient updating device that updates a filter coefficient of a plurality of filters of a filter layer in which the plurality of filters are connected in a first plurality of stages with respect to received data, and includes: a deriving unit that derives a filter coefficient of each of the plurality of filters in one or a plurality of stages included in the first plurality of stages, by means of output data being output from the last stage of the first plurality of stages; and an updating unit that updates each of the filter coefficients.

### Advantageous Effects of Invention

A filter coefficient updating device and the like according to the present invention reduce a calculation amount for signal distortion compensation.

### BRIEF DESCRIPTION OF DRAWINGS

FIG. 1 is a conceptual diagram illustrating a configuration example of an optical communication system that is general and to which a demodulating unit according to an example embodiment is applicable.

FIG. 2 is a conceptual diagram illustrating a general processing example of signal distortion compensation processing for demodulation of received data.

FIG. 3 is a conceptual diagram illustrating general MIMO signal processing having a 2×2 configuration in which polarization fluctuation compensation processing is performed.

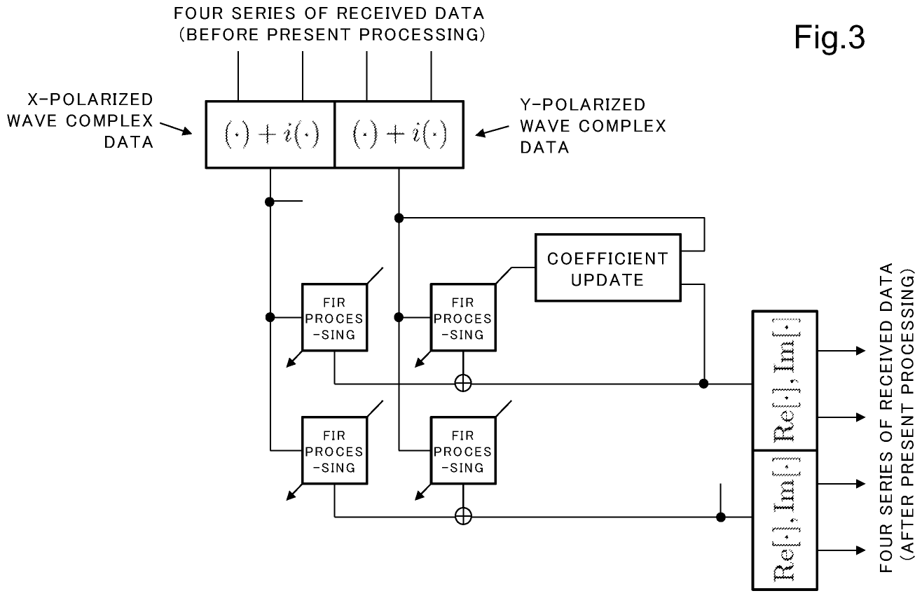

FIG. 4 is a conceptual diagram illustrating real MIMO signal processing in which received data of an I component and received data of a Q component are independently processed.

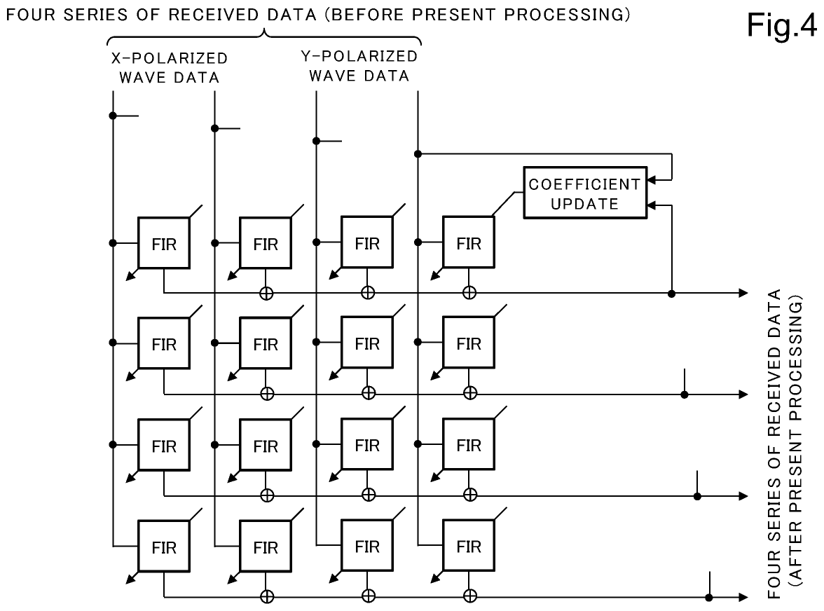

FIG. 5 is a conceptual diagram illustrating MIMO signal processing called widely linear (WL) filter processing.

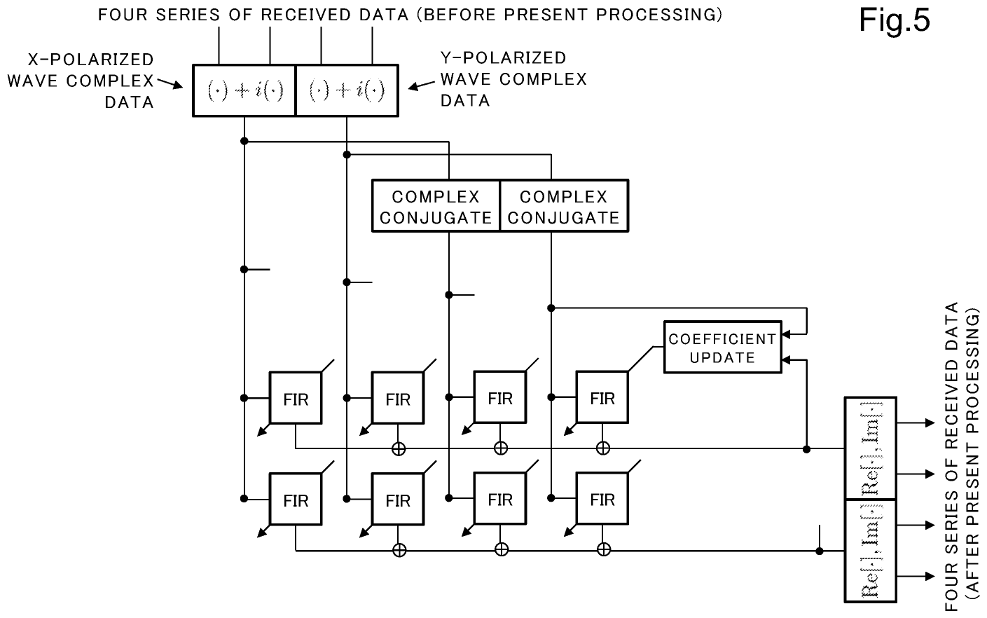

FIG. 6 is a conceptual diagram illustrating a demodulating unit according to the present example embodiment.

FIG. 7 is an image illustrating filter coefficient update processing according to the present example embodiment.

FIG. 8 is a diagram illustrating a result (no. 1) of computing a constellation of received data.

FIG. 9 is a diagram illustrating a result (no. 2) of computing a constellation of received data.

FIG. 10 is a diagram illustrating a result (no. 3) of computing a constellation of received data.

FIG. 11 is a conceptual diagram illustrating a minimum configuration of a filter coefficient updating device according to an example embodiment.

### EXAMPLE EMBODIMENT

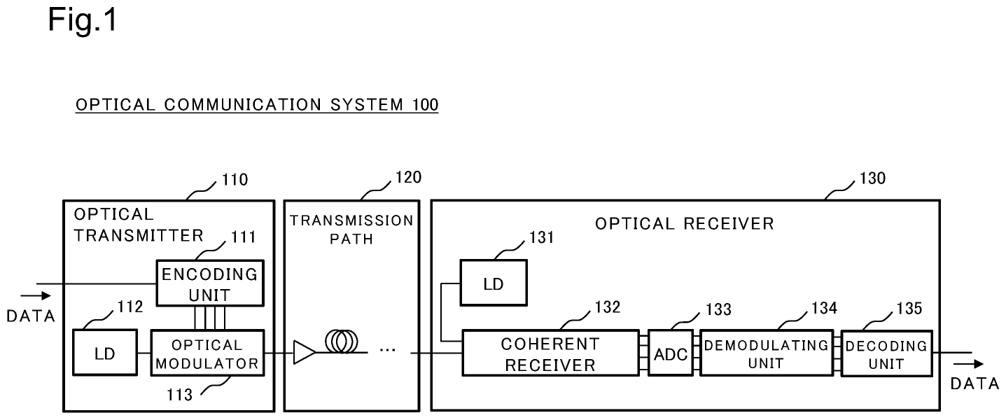

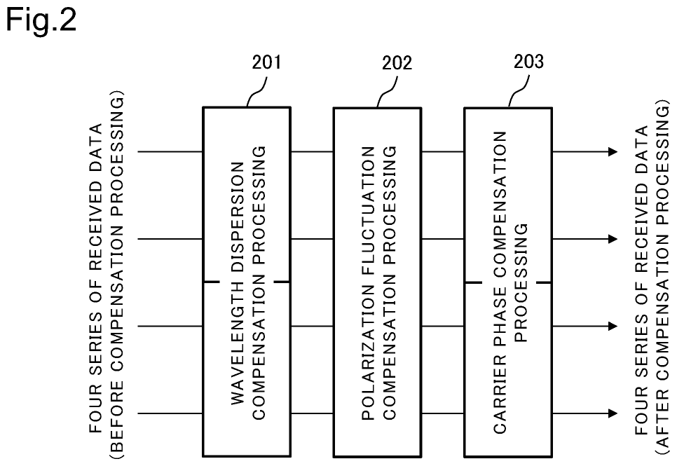

A configuration example of an optical communication system to which the demodulating unit 134 according to the present example embodiment is applied is the optical communication system 100 illustrated in FIG. 1. However, a method of equalization processing for demodulation performed in the demodulating unit 134 is different from that illustrated in FIG. 2.

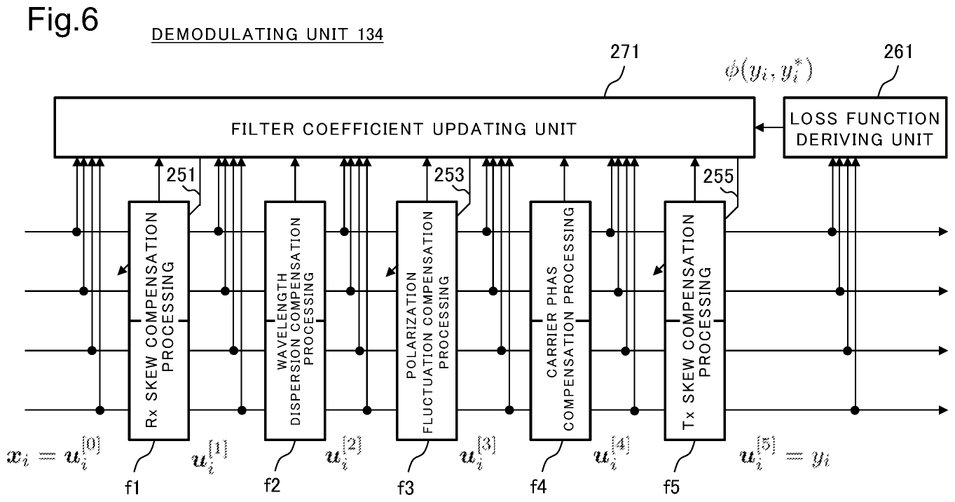

FIG. 6 is a conceptual diagram illustrating the demodulating unit 134 of the optical receiver 130 in the optical communication system 100 according to the present example embodiment illustrated in FIG. 1.

The demodulating unit 134 includes filter layers f1 to f5, a loss function deriving unit 261, and a filter coefficient updating unit 271.

Four series of received data before demodulation processing, that is, before equalization processing are input to the demodulating unit 134 as input data xᵢ (i is an integer of 1 to 4. The same applies hereinafter.). The four series of received data before equalization processing include two series of X-polarized wave data (xᵢ where i is 1 or 2) acquired from an X-polarized wave and two series of Y-polarized wave data (xᵢ where i is 3 or 4) acquired from a Y-polarized wave.

The filter layers f1 to f5 are filter layers connected in first to fifth stages, respectively, when viewed from an input side of the four series of received data before equalization processing. In the figure, xᵢ is written as equal to uᵢ^{[0]}. Output data uᵢ^{[1]} to uᵢ^{[5]} in the figure are output data from the filter layers f1 to f5, respectively. The output data uᵢ^{[5]} are equal to output data yᵢ being last output data from the demodulating unit 134.

When demodulating the four series of received data before equalization processing by performing equalization processing, the demodulating unit 134 performs each piece of compensation processing by using each filter. The compensation processing is Rx skew compensation processing, wavelength dispersion compensation processing, polarization fluctuation compensation processing, carrier phase compensation processing, and Tx skew compensation processing. Contents of the pieces of compensation processing are as described in paragraphs of Background Art.

The filter layer f1 is for performing the Rx skew compensation processing. The filter layer f2 is for performing the wavelength dispersion compensation processing. The filter layer f3 is for performing the polarization fluctuation compensation processing.

The filter layer f4 is for performing the carrier phase compensation processing. The filter layer f5 is for performing the Tx skew compensation processing.

The filter coefficient updating unit 271 updates a filter coefficient of each filter of the filter layers f1 to f5. At that time, the filter coefficient updating unit 271 performs Rx skew compensation processing 251 on the filter layer f1. The filter coefficient updating unit 271 performs polarization fluctuation compensation processing 253 on the filter layer f3. The filter coefficient updating unit 271 performs Tx skew compensation processing 255 on the filter layer f5.

The filter coefficient updating unit 271 derives an update amount for updating a filter coefficient of each filter from a loss function derived by the loss function deriving unit 261. Herein, the update amount is a value representing a degree and an increase or decrease in changing a filter coefficient. The loss function is a function of output data and is an implicit function of a filter coefficient, representing a deviation from a desired state of a received signal.

The loss function deriving unit 261 derives a loss function from each of four series of received data after equalization processing from the filter layer f5 being an output of the last stage of the demodulating unit 134, and inputs the loss function to the filter coefficient updating unit 271.

Any of the compensation processing described in paragraphs of Background Art is for updating a filter coefficient of a filter of a filter layer by means of a direct output from the filter of the filter layer in each stage. In contrast to this, the compensation processing that the demodulating unit 134 performs is for updating not only a filter coefficient of a filter of a filter layer in an immediately preceding stage, but also a filter coefficient of a filter of a filter layer in a further preceding stage. The compensation processing that the demodulating unit 134 performs is performed based on an output (uᵢ^{[5]}) from a filter of a filter layer in the last stage of filter layers connected in a plurality of stages. The compensation processing that the demodulating unit 134 performs is different in this point from general compensation processing.

As the filters of the filter layers f1 to f5, those in consideration of a characteristic of a signal distortion to be compensated for are selected. In description therefor, it is assumed that the filters of the filter layers f1 to f5 are all FIR filters.

For the Rx skew compensation processing and the Tx skew compensation processing, a WL filter needs to be used, as described above. In principle, mixing between an X-polarized wave and a Y-polarized wave may not be considered. In view of this, as the filters of the filter layers f1 and f5, two WL FIR filters having a 2×1 configuration are used for each polarized wave. In addition, filter coefficients thereof are adaptively updated by the Rx skew compensation processing 251 and the Tx skew compensation processing 255 performed by the filter coefficient updating unit 271.

For the wavelength dispersion compensation processing, two SL FIR filters without MIMO (having a 1×1 configuration) are used for each polarized wave. In addition, filter coefficients of the filters are fixed.

As the filter layer f3 for use in the polarization fluctuation compensation processing, an FIR filter having a 2×2 configuration is used. In addition, a filter coefficient thereof is adaptively updated by the polarization fluctuation compensation processing 253 performed by the filter coefficient updating unit 271.

As the filter layer f4 for use in the carrier phase compensation processing, two SL one-tap FIR filters having a 1×1 configuration are used for each polarized wave. A phase amount to be compensated for by the carrier phase compensation processing is calculated based on a filter output of the last stage, separately by using an unillustrated method. For calculation of the phase amount to be compensated for, a digital phase-locked loop (PLL) using general M multiplication or temporary determination can be used. The number of taps of each FIR filter other than in the carrier phase compensation processing is selected individually for a signal distortion to be subjected to compensation processing.

The filter coefficient updating unit 271 performs an update amount relating to update of each of the filter coefficients from a loss function determined by a filter output of the last stage, by using stochastic gradient descent in such a way as to minimize the loss function. In order to use the stochastic gradient descent, a gradient of the loss function relating to each of the filter coefficients is needed. This can be computed by error back propagation as will be described below.

Herein, consider that L stages of filters are connected in cascade. In a case in FIG. 6, the number of stages is L=5 because there are 5 stages of the filter layers f1 to f5. Herein, it is assumed that a filter output and a filter input of an 1-th stage at a time k (k is an integer) are u^{[1]}ᵢ[k] and u^{[1-1]}ᵢ[k] respectively. i=1 and 2 represent polarized waves. When i is a value at most twice the number of modes, the above can be easily expanded to a case of spatial multiplex transmission or the like. When a bold letter represents a vector and a length of an input vector is M^{[1]}ᵢₙ and M^{[1]}ₒᵤₜ,

[Mathematical1]

uᵢ^{[l]}[k]=(uᵢ^{[l]}[k],uᵢ^{[l]}[k−1], . . . ,uᵢ^{[l]}[k−Mₒᵤₜ^{[l]}+1])^{T} (1)

and

[Mathematical2]

uᵢ^{[t-1]}[k]=(uᵢ^{[t-1]}[k],uᵢ^{[t-1]}[k−1], . . . ,uᵢ^{[t-1]}[k−Mᵢₙ^{[t]}+1])^{T} (2)

hold. Herein, T represents a transpose.

When a filter in the 1-th stage is an SL MIMO filter (including a case of a 1×1 configuration),

$$\begin{matrix}[ Mathematical 3 ] & \\ {u}_{i}^{[ l ]} [ k ] = {{\sum }_{j = 1}}^{2} {h}_{ij}^{[ l ] †} {u}_{j}^{[ l - 1 ]} [ k ] & ( 3 )\end{matrix}$$

holds. † represents a Hermitian conjugate. Herein,

[Mathematical4]

hᵢⱼ^{[l]}=(hᵢⱼ^{[l]}[0],hᵢⱼ^{[l]}[1], . . . ,hᵢⱼ^{[l]}[M^{[l]}−1])^{T} (4)

represents an M^{[1]}-tap FIR filter coefficient. Herein,

[Mathematical5]

M^{[l]}=Mᵢₙ^{[l]}. . . Mₒᵤₜ^{[l]}+1 (5)

holds. From this,

$$\begin{matrix}[ Mathematical 6 ] & \\ {u}_{i}^{[ l ]} [ k ] = {{\sum }_{j = 1}}^{2} {H}_{ij}^{[ l ] *} {u}_{j}^{[ l - 1 ]} [ k ] & ( 6 )\end{matrix}$$

holds. Herein, * represents a complex conjugate, and

$$\begin{matrix}[ Mathematical 7 ] & \\ {H}_{ij}^{[ l ]} = ( \begin{matrix}{h}_{ij}^{[ l ]} [ 0 ] & {h}_{ij}^{[ l ]} [ 1 ] & ⋯ & {h}_{ij}^{[ l ]} [ {M}^{[ l ]} - 1 ] & 0 & ⋯ & 0 \\ 0 & ⋱ & ⋱ & & ⋱ & ⋱ & ⋮ \\ ⋮ & & & & & & 0 \\ 0 & ⋯ & 0 & {h}_{ij}^{[ l ]} [ 0 ] & {h}_{ij}^{[ l ]} [ 1 ] & ⋯ & {h}_{ij}^{[ l ]} [ {M}^{[ l ]} - 1 ]\end{matrix} ) & ( 7 )\end{matrix}$$

holds. When the equation (6) is transformed,

$$\begin{matrix}[ Mathematical 8 ] & \\ {u}_{i}^{[ l ]} [ k ] = {{\sum }_{j = 1}}^{2} {U}_{j}^{[ l - 1 ]} [ k ] {h}_{ij}^{[ l ] *} & ( 8 )\end{matrix}$$

$$and$$

$$\begin{matrix}[ Mathematical 9 ] & \\ {U}_{j}^{[ l - 1 ]} = ( \begin{matrix}{u}_{j}^{[ l - 1 ]} [ k ] & {u}_{j}^{[ l - 1 ]} [ k - 1 ] & ⋯ & {u}_{j}^{[ l - 1 ]} [ k - {M}^{[ l ]} + 1 ] \\ {u}_{j}^{[ l - 1 ]} [ k - 1 ] & {u}_{j}^{[ l - 1 ]} [ k - 2 ] & ⋯ & {u}_{j}^{[ l - 1 ]} [ k - {M}^{[ l ]} ] \\ ⋮ & & & ⋮ \\ {u}_{j}^{[ l - 1 ]} [ k - {M}_{out}^{[ l ]} + 1 ] & {u}_{j}^{[ l - 1 ]} [ k - {M}_{out}^{[ l ]} ] & ⋯ & {u}_{j}^{[ l - 1 ]} [ k - {M}_{in}^{[ l ]} + 1 ]\end{matrix} ) & ( 9 )\end{matrix}$$

hold.

When a filter in the 1-th stage is a WL MIMO filter (including a case of a 2×1 configuration),

$$\begin{matrix}[ Mathematical 10 ] & \\ {u}_{i}^{[ l ]} [ k ] = {{\sum }_{j = 1}}^{2} {h}_{ij}^{[ l ] †} {u}_{j}^{[ l - 1 ]} [ k ] + {{\sum }_{j = 1}}^{2} {h}_{* ij}^{[ l ] †} {u}_{j}^{[ l - 1 ] *} [ k ] & ( 10 )\end{matrix}$$

holds. In the WL MIMO filter, h^{[1]}ⱼ and

[Mathematical11]

h_{*ij}^{[l]}=(h_{*ij}^{[l]}[0],h_{*ij}^{[l]}[1], . . . ,h_{*ij}^{[l]}[M^{[l]}−1])^{T} (11)

are filter coefficients. Similarly to the case described above, when

$$\begin{matrix}[ Mathematical 12 ] & \\ {H}_{* ij}^{[ l ]} = ( \begin{matrix}{h}_{* ij}^{[ l ]} [ 0 ] & {h}_{* ij}^{[ l ]} [ 1 ] & ⋯ & {h}_{* ij}^{[ l ]} [ {M}^{[ l ]} - 1 ] & 0 & ⋯ & 0 \\ 0 & ⋱ & ⋱ & & ⋱ & ⋱ & ⋮ \\ ⋮ & & & & & & 0 \\ 0 & ⋯ & 0 & {h}_{* ij}^{[ l ]} [ 0 ] & {h}_{* ij}^{[ l ]} [ 1 ] & ⋯ & {h}_{* ij}^{[ l ]} [ {M}^{[ l ]} - 1 ]\end{matrix} ) & ( 12 )\end{matrix}$$

holds,

$$\begin{matrix}[ Mathematical 13 ] & \\ \begin{matrix}{u}_{i}^{[ l [} [ k ] = {{\sum }_{j = 1}}^{2} {H}_{ij}^{[ l ] *} {u}_{j}^{[ l - 1 ]} [ k ] + {{\sum }_{j = 1}}^{2} {H}_{* ij}^{[ l ] *} {u}_{j}^{[ l - 1 ] *} [ k ] \\ = {{\sum }_{j = 1}}^{2} {U}_{j}^{[ l - 1 ]} [ k ] {h}_{ij}^{[ l ] *} + {{\sum }_{j = 1}}^{2} {U}_{j}^{[ l - 1 ] *} [ k ] {h}_{* ij}^{[ l ] *}\end{matrix} & ( 13 )\end{matrix}$$

holds.

Herein, it is assumed that an input to a filter in a first stage is

[Mathematical14]

xᵢ[k]=uᵢ^{[0]}[k] (14)

It is assumed that an output of a filter in the last L-th stage is M^{[L]}ₒᵤₜ=1 and is

[Mathematical15]

yᵢ[k]=uᵢ^{[L]} (15)

. yᵢ[k] is calculated from xᵢ[k] by using the above equation. A loss function φ is constructed from the filter output, that is, yᵢ[k], of the last stage. The loss function φ can be constructed by using a method such as CMA or DDLMS. For example, in a general CMA, magnitude of an error from a desired value r for amplitude of a filter output

$$\begin{matrix}[ Mathematical 16 ] & \\ ϕ [ k ] = {{\sum }_{i = 1}}^{2} {( {r}^{2} - {\vert {y}_{i} [ k ] \vert}^{2} )}^{2} & ( 16 )\end{matrix}$$

is a loss function. Each of the filter coefficients is updated by using the stochastic gradient descent in such a way as to minimize the loss function. Since the filter coefficient of this time takes a complex value, the Wirtinger derivative method may be used to update a filter coefficient ξ* in such a way as to minimize the function as follows.

$$\begin{matrix}[ Mathematical 17 ] & \\ {ξ}^{*} \to {ξ}^{*} - 2 α \frac{\partial ϕ}{\partial ξ} & ( 17 )\end{matrix}$$

Herein, α is a step size for controlling magnitude of update. The multiple layers of filters connected in cascade of this time are configured to be differentiable as a whole, as in the above equation. Thus, a gradient relating to each of the filter coefficients can be computed by using a method of the error back propagation, and accordingly, update using the stochastic gradient descent can be performed. At that time, a complex variable z and a complex conjugate z* thereof are handled independently and computed by using the Wirtinger derivative method.

For the output of the filter last stage, when the above loss function of CMA is used,

$$\begin{matrix}[ Mathematical 18 ] & \\ \frac{\partial ϕ}{\partial {y}_{i} [ k ]} = - 2 {e}_{i} {y}_{i}^{*} [ k ] & ( 18 )\end{matrix}$$

$$\begin{matrix}[ Mathematical 19 ] & \\ \frac{\partial ϕ}{\partial {y}_{i}^{*} [ k ]} = - 2 {e}_{i} {y}_{i} [ k ] & ( 19 )\end{matrix}$$

$$and$$

$$\begin{matrix}[ Mathematical 20 ] & \\ {e}_{i} = {r}^{2} - {\vert {y}_{i} [ k ] \vert}^{2} & ( 20 )\end{matrix}$$

hold. This is a gradient of the loss function relating to the filter output of the last L-th stage. From the gradient of the loss function relating to the filter output of the 1-th stage, a filter coefficient of the 1-th stage of the loss function and a gradient relating to the filter input can be calculated by using the error back propagation as follows.

When a filter in the 1-th stage is an SL MIMO filter, differentials are computed as

$$\begin{matrix}[ Mathematical 21 ] & \\ \frac{\partial ϕ}{\partial {h}_{ij}^{[ l ]}} = {U}_{j}^{[ l - 1 ] †} [ k ] \frac{\partial ϕ}{\partial {u}_{i}^{[ l ] *} [ k ]} & ( 21 )\end{matrix}$$

$$\begin{matrix}[ Mathematical 22 ] & \\ \frac{\partial ϕ}{\partial {u}_{j}^{[ l - 1 ]} [ k ]} = {{\sum }_{i = 1}}^{2} {H}_{ij}^{[ l ] †} \frac{\partial ϕ}{\partial {u}_{i}^{[ l ]} [ k ]} & ( 22 )\end{matrix}$$

$$and$$

$$\begin{matrix}[ Mathematical 23 ] & \\ \frac{\partial ϕ}{\partial {u}_{j}^{[ l - 1 ] *} [ k ]} = {{\sum }_{i = 1}}^{2} {H}_{ij}^{[ l ] T} \frac{\partial ϕ}{\partial {u}_{i}^{[ l ] *} [ k ]} . & ( 23 )\end{matrix}$$

When a filter in the 1-th stage is a WL MIMO filter, differentials are computed as

$$\begin{matrix}[ Mathematical 24 ] & \\ \frac{\partial ϕ}{\partial {h}_{ij}^{[ l ]}} = {U}_{j}^{[ l - 1 ] †} [ k ] \frac{\partial ϕ}{\partial {u}_{i}^{[ l ] *} [ k ]} & ( 24 )\end{matrix}$$

$$\begin{matrix}[ Mathematical 25 ] & \\ \frac{\partial ϕ}{\partial {h}_{* ij}^{[ l ]}} = {U}_{j}^{[ l - 1 ] T} [ k ] \frac{\partial ϕ}{\partial {u}_{i}^{[ l ] *} [ k ]} & ( 25 )\end{matrix}$$

$$\begin{matrix}[ Mathematical 26 ] & \\ \frac{\partial ϕ}{\partial {u}_{j}^{[ l - 1 ]} [ k ]} = {{\sum }_{i = 1}}^{2} ( {H}_{ij}^{[ l ] †} \frac{\partial ϕ}{\partial {u}_{i}^{[ l ]} [ k ]} + {H}_{* ij}^{[ l ] T} \frac{\partial ϕ}{\partial {u}_{i}^{[ l ] *} [ k ]} ) & ( 26 )\end{matrix}$$

$$and$$

$$\begin{matrix}[ Mathematical 27 ] & \\ \frac{\partial ϕ}{\partial {u}_{j}^{[ l - 1 ] *} [ k ]} = {{\sum }_{i = 1}}^{2} ( {H}_{* ij}^{[ l ] †} \frac{\partial ϕ}{\partial {u}_{i}^{[ l ]} [ k ]} + {H}_{ij}^{[ l ] T} \frac{\partial ϕ}{\partial {u}_{i}^{[ l ] *} [ k ]} ) & ( 27 )\end{matrix}$$

By using the equations, from the gradient of the loss function relating to the filter output of the 1-th stage, a filter coefficient of the 1-th stage of the loss function and a gradient relating to the filter input are computed by using the error back propagation. When the filter coefficient of the 1-th stage is adaptively controlled, the filter coefficient is updated according to the expression (17). When the filter coefficient of the 1-th stage is handled fixedly, only a gradient relating to merely the filter input may be computed for a filter in the 1-th stage. This is repeated from the last L-th stage, and thereby a gradient relating to the loss function is computed and a filter coefficient update amount is calculated for all the filter coefficients up to an initial first filter.

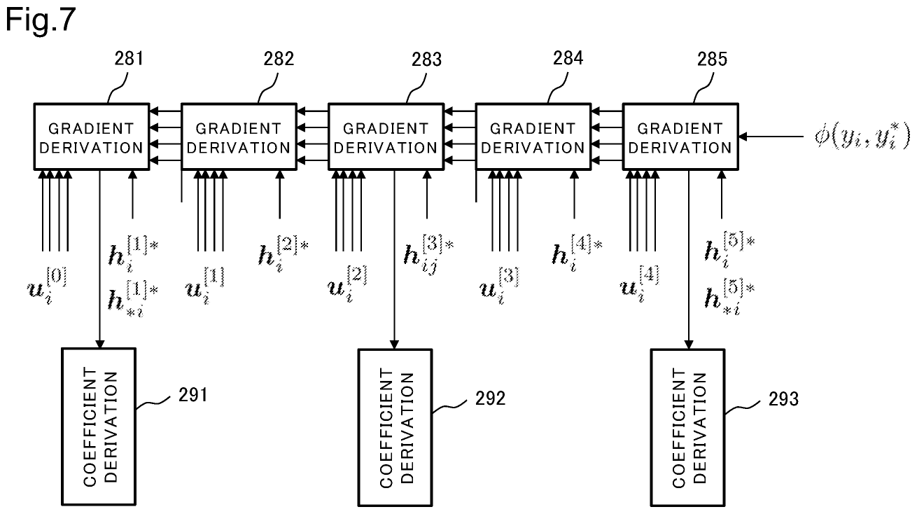

FIG. 7 is an image illustrating processing of updating a filter coefficient of each filter layer performed by the filter coefficient updating unit 271 of the demodulating unit 134 having multistage filter layers in FIG. 6.

First, the filter coefficient updating unit 271 performs gradient derivation 285 and coefficient derivation 293 from a gradient of a loss function φ(yᵢ, y*ᵢ) input from the loss function deriving unit 261. The gradient derivation 285 is derivation of a gradient relating to input data uᵢ^{[4]} and filter coefficients hᵢ^{[5]}* and h_{*i}^{[5]}* of the filter layer f5. The coefficient derivation 293 is derivation of the filter coefficients hᵢ^{[5]}* and h_{*i}^{[5]}* for updating each filter of the filter layer f5. The filter coefficient updating unit 271 updates a filter coefficient of each filter of the filter layer f5 by using the derived filter coefficients hᵢ^{[5]}* and h_{*i}^{[5]*}.

Next, the filter coefficient updating unit 271 performs gradient derivation 284 that is derivation of a gradient relating to input data uᵢ^{[3]} of the filter layer f4 from the derived gradient of uᵢ^{[4]}.

Next, the filter coefficient updating unit 271 performs gradient derivation 283 and coefficient derivation 292 from the derived gradient of uᵢ^{[3]}. The gradient derivation 283 is derivation of a gradient relating to input data uᵢ^{[2]} and a filter coefficient hᵢⱼ^{[3]}* of the filter layer f3. The coefficient derivation 293 is derivation of the filter coefficient hᵢⱼ^{[3]}* for updating a filter coefficient of each filter of the filter layer f3. The filter coefficient updating unit 271 updates a filter coefficient of each filter of the filter layer f3 by using the derived filter coefficient hᵢⱼ^{[3]*}.

Next, the filter coefficient updating unit 271 performs gradient derivation 282 that is derivation of a gradient relating to input data u^{[1]} of the filter layer f2 from the derived gradient of u^{[2]}.

Then, the filter coefficient updating unit 271 performs gradient derivation 281 and coefficient derivation 291 from the derived gradient of u^{[1]}. The gradient derivation 281 is derivation of a gradient relating to input data uᵢ^{[0]} and filter coefficients hᵢ^{[1]}* and h_{*i}^{[1]}* of the filter layer f1. The coefficient derivation 291 is derivation of the filter coefficients hᵢ^{[1]*} and h_{*i}^{[1]}* for updating a filter coefficient of each filter of the filter layer f1. The filter coefficient updating unit 271 updates a filter coefficient of each filter of the filter layer f1 by using the derived filter coefficients hᵢ^{[1]} * and h_{*i}^{[1]}*.

As for each filter of the filter layer f2 including a filter for wavelength dispersion compensation, from an accumulated wavelength dispersion amount D to be compensated for, a filter coefficient is determined by

$$\begin{matrix}[ Mathematical 28 ] & \\ {H}_{CD} ( ω ) = exp ( i \frac{{λ}^{2}}{4 π c} D {ω}^{2} ) . & ( 28 )\end{matrix}$$

Herein, λ is a wavelength of an optical signal, and c is a speed of light.

A filter coefficient of each filter of the filter layer f4 for the carrier phase compensation processing is

[Mathematical29]

h_{CPEi}=exp(−iθᵢ[k]) (29)

, where θᵢ [k] is determined based on the filter output of the last stage, as described above.

Through the above processing, it is possible to update all the filter coefficients of the filters of the filter layers f1, f3, and f5, which should be adaptively controlled, in such a way that the filter output of the last stage approaches a desired state.

The demodulating unit 134 in FIG. 6 is able to perform any of the Rx skew compensation processing, the wavelength dispersion compensation processing, the polarization fluctuation compensation processing, the carrier phase compensation processing, and the Tx skew compensation processing. At the same time, the demodulating unit 134 does not need to use a large-scale WL filter or special wavelength dispersion compensation processing as in the method in NPL 2 or 3. Thus, the demodulating unit 134 is able to reduce computational complexity when updating a filter coefficient for compensation processing.

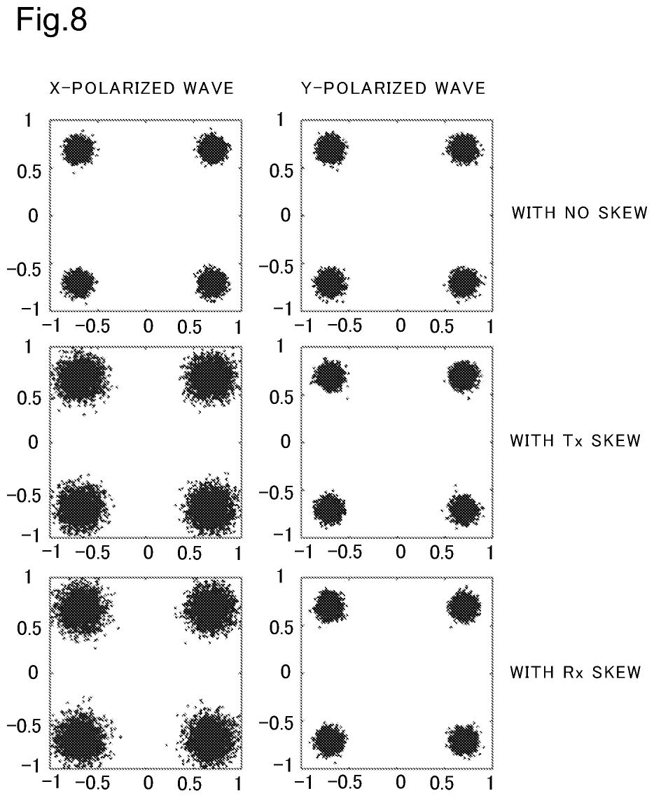

FIGS. 8 to 10 are diagrams illustrating a result of simulating a constellation of received data. For the simulation, a model was used in which a polarization-multiplexed QPSK signal was transmitted, a wavelength dispersion equivalent to 100 km of single-mode fiber propagation was given, and coherent reception was performed. Further, a constellation after equalization processing of received data was evaluated under three types of conditions: when neither a transmitter nor a receiver has an IQ skew, when a transmitting-side X-polarized wave has an IQ skew, and when a receiving-side X-polarized wave has an IQ skew.

FIG. 8 is a diagram illustrating a result of computing the constellation when general compensation processing illustrated in FIG. 2 is performed. The constellation in FIG. 8 is satisfactory in the absence of the IQ skew. However, in a case of FIG. 8, since it is assumed that the signal distortion caused by the IQ skew is not compensated, the constellation deteriorates when the IQ skew is in either a transmitter or a receiver.

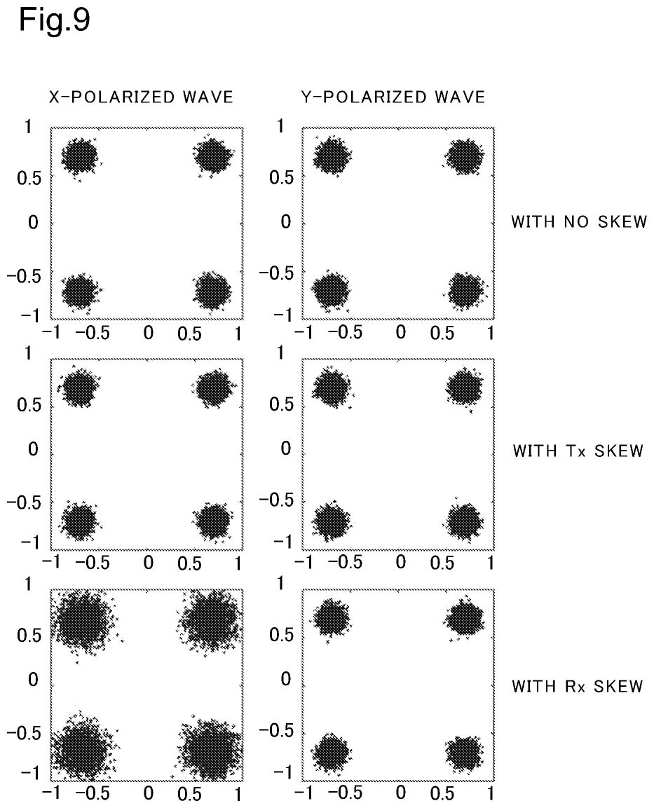

FIG. 9 is a diagram illustrating a result of computation when a WL filter having a 4×2 configuration is used for the polarization fluctuation compensation processing in equalization signal processing illustrated in FIG. 1. In a case of FIG. 9, a satisfactory constellation can be acquired in the presence of the IQ skew in a transmitter. However, since the wavelength dispersion occurring in a transmission path occurs, a configuration in which a WL filter is applied simply after the wavelength dispersion compensation processing does not compensate for the signal distortion caused by the IQ skew in a receiver, and the constellation deteriorates.

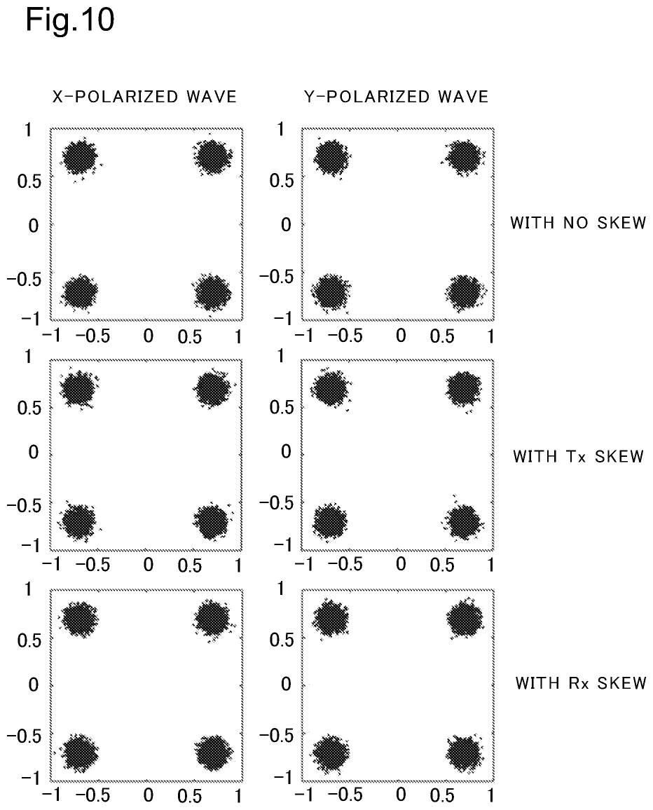

FIG. 10 is a diagram illustrating a result of computation when the compensation method according to the present example embodiment is applied. When the compensation method according to the present example embodiment is applied, the compensation processing is effective for the IQ skew in a receiver as well in comparison with the cases in FIGS. 8 and 9, and a satisfactory constellation can be computed.

### Advantageous Effects

Through the compensation processing described above, the demodulating unit according to the present example embodiment is able to compensate for the signal distortions attributable to any of the Rx skew, the wavelength dispersion, the polarization fluctuation, the carrier phase fluctuation, and the Tx skew. At the same time, the demodulating unit according to the present example embodiment does not need to use a large-scale WL filter or special wavelength dispersion compensation processing as in the method in NPL 2 or 3. Thus, the demodulating unit according to the present example embodiment is able to reduce computational complexity of a filter for compensation processing.

By applying the compensation processing according to the present example embodiment, a filter can be easily extended to have a further increased number of layers, in order to deal with a signal distortion due to another cause other than the Rx skew, the wavelength dispersion, the polarization fluctuation, the carrier phase fluctuation, and the Tx skew. A conventional filter can be further connected after a filter in the last stage. Further, by applying the compensation processing according to the present example embodiment, processing of compensating for a signal distortion due to a cause that does not need to be considered in an application to be applied can be easily deleted.

The compensation method according to the present example embodiment performs update based on a filter output of the last stage for which compensation processing is performed on signal distortions due to all causes, instead of performing update based on a direct output of a filter as in an adaptive equalization filter generally used in optical fiber communication. Thus, the compensation method according to the present example embodiment is able to compensate for a signal distortion with higher precision.

When the compensation method according to the present example embodiment is applied, an individual value can be set for a step size for updating a filter coefficient of each filter. Further, filter coefficient update can be stopped by setting a step size for filter coefficient update of some filters to 0, and only a filter coefficient of one or a few target filters can be updated, or, thereby, filter coefficient update of filters can be sequentially performed. For example, consider that the skews in a transmitter and a receiver do not change significantly during operation even when adaptive control is required. In that case, the filters for the Tx skew compensation processing and the Rx skew compensation processing can be operated in a fixed manner without update after the filter coefficient is determined by the above method at a time of operation start.

Further, when the compensation method according to the present example embodiment is applied, it is also possible to mount the filters on different pieces of hardware, such as, for example, processing up to the polarization fluctuation compensation processing is performed by one circuit and processing thereafter is performed by another circuit. In this case, filter coefficient update may be performed by still another piece of hardware, and is performed by integrating pieces of information from the circuits.

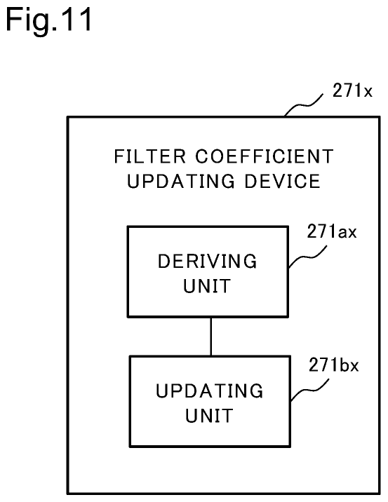

FIG. 11 is a conceptual diagram illustrating a configuration of a filter coefficient updating device 271x being a minimum configuration of a filter coefficient updating device according to an example embodiment.

The filter coefficient updating device 271x is a filter coefficient updating device that updates a filter coefficient of a plurality of filters of a filter layer in which the plurality of filters are connected in a first plurality of stages with respect to received data. The filter coefficient updating device 271x includes a deriving unit 271ax and an updating unit 271bx.

The deriving unit 271ax derives a filter coefficient of each of the plurality of filters in one or a plurality of stages included in the first plurality of stages, by means of output data output from the last stage of the first plurality of stages. The updating unit 271bx updates each of the filter coefficients.

The filter coefficient updating device 271x derives a filter coefficient of each of the plurality of filters in one or a plurality of stages included in the first plurality of stages, by means of output data output from the last stage of the first plurality of stages.

Thus, the filter coefficient updating device 271x is able to reduce computational complexity required for derivation of a filter coefficient, in comparison with a general method described in paragraphs of Background Art. In other words, the filter coefficient updating device 271x reduces a calculation amount for signal distortion compensation.

Thus, with the configuration, the filter coefficient updating device 271x exhibits an advantageous effect described in paragraphs of

### Advantageous Effects of Invention

In the above, each of the example embodiments of the present invention has been described. However, the present invention is not limited to the above-described example embodiments, but can be further modified, substituted, and adjusted within a scope not departing from the basic technical idea of the present invention. For example, a configuration of an element illustrated in each of the drawings is one example for assisting understanding of the present invention, and is not limited to the configuration illustrated in the drawings.

The example embodiments of the present invention can be described as, but not limited to, the following supplementary notes.

### (Supplementary Note 1)

A filter coefficient updating device that updates a filter coefficient of a plurality of filters of a filter layer in which the plurality of filters are connected in a first plurality of stages with respect to received data, the filter coefficient updating device including:

a deriving unit that derives a filter coefficient of each of the plurality of filters in one or a plurality of stages included in the first plurality of stages, by means of output data being output from the last stage of the first plurality of stages; and

an updating unit that updates each of the filter coefficients.

### (Supplementary Note 2)

The filter coefficient updating device according to supplementary note 1, wherein

the deriving unit derives a filter coefficient of each of the plurality of filters, by means of a difference from desired data of the output data.

### (Supplementary Note 3)

The filter coefficient updating device according to supplementary note 2, wherein

the deriving unit acquires the difference as a function.

### (Supplementary Note 4)

The filter coefficient updating device according to any one of supplementary notes 1 to 3, wherein the filter layer includes either a widely linear filter or a strictly linear filter.

### (Supplementary Note 5)

The filter coefficient updating device according to any one of supplementary notes 1 to 4, wherein the deriving unit derives a filter coefficient of each of the plurality of filters in the one or the plurality of stages, by means of error back propagation.

### (Supplementary Note 6)

The filter coefficient updating device according to supplementary note 5, wherein the deriving unit derives the filter coefficient of each of the filter of the plurality of filters in the one or the plurality of stages, by computing a gradient relating to the filter coefficient by means of the error back propagation.

### (Supplementary Note 7)

A filter device including the filter coefficient updating device according to any one of supplementary notes 1 to 6 and the filter layer.

### (Supplementary Note 8)

A demodulating device including the filter device according to supplementary note 7 and demodulating the received data.

### (Supplementary Note 9)

The demodulating device according to supplementary note 8, wherein the demodulation is performed by equalization processing on the received data.

### (Supplementary Note 10)

The demodulating device according to supplementary note 8 or 9, wherein the received data are acquired from a quadrature amplitude modulated received signal.

### (Supplementary Note 11)

The demodulating device according to any one of supplementary notes 8 to 10, wherein the received data are acquired from a received signal that has reached a receiver by transmitting through an optical fiber.

### (Supplementary Note 12)

The demodulating device according to supplementary note 11, wherein the plurality of filters in a stage of the first plurality of stages are for compensating for a failure in the received data attributable to a distortion of the received signal due to a first cause, and the plurality of filters in another stage of the first plurality of stages are for compensating for a failure in the received data due to a second cause being a cause different from the first cause.

### (Supplementary Note 13)

The demodulating device according to supplementary note 12, wherein the first cause and the second cause are any of a Tx skew being a time skew between an in-phase component and a quadrature component of the received signal generated in a transmitting source of the received signal, a wavelength dispersion generated by the transmission, a polarization state fluctuation and a polarization mode dispersion being generated by the transmission, a frequency offset and a phase offset between a carrier of a transmitting signal in the transmitting source of the received signal and local oscillator light of a receiver receiving the received signal, and an Rx skew being the time skew of the received signal generated on a receiving side of the received signal.

### (Supplementary Note 14)

The demodulating device according to supplementary note 13, wherein the first cause includes at least any of the Tx skew, the wavelength dispersion, the polarization state fluctuation and the polarization mode dispersion, the frequency offset, and the phase offset, and the second cause is the Rx skew.

### (Supplementary Note 15)

A receiving device including the demodulating device according to any one of supplementary notes 9 to 14 and receiving the received data.

### (Supplementary Note 16)

A transmitting and receiving system including the receiving device according to supplementary note 15 and a transmitting device that transmits the received data to the receiving device.

### (Supplementary Note 17)

A filter coefficient updating method of updating a filter coefficient of a plurality of filters of a filter layer in which the plurality of filters are connected in a first plurality of stages with respect to received data, the filter coefficient updating method including:

deriving a filter coefficient of each of the plurality of filters in one or a plurality of stages included in the first plurality of stages, by means of output data being output from the last stage of the first plurality of stages; and

updating each of the filter coefficients.

### (Supplementary Note 18)

A filter coefficient updating program causing a computer to execute processing of updating a filter coefficient of a plurality of filters of a filter layer in which the plurality of filters are connected in a first plurality of stages with respect to received data, the filter coefficient updating program causing the computer to execute:

processing of deriving a filter coefficient of each of the plurality of filters in one or a plurality of stages included in the first plurality of stages, by means of output data being output from the last stage of the first plurality of stages; and

processing of updating each of the filter coefficients.

The received data in the above supplementary notes are, for example, four series of received data input to the demodulating unit 134 in FIG. 6. The first plurality of stages are, for example, five stages being the number of stages of the filter layers f1 to f5. The filter layer is, for example, the filter layers f1 to f5 in FIG. 6.

The one or a plurality of stages are, for example, one or a plurality of stages among the stages of the filter layers f1 to f5 in FIG. 6. The plurality of filters are, for example, filters included in each of the filter layers f1 to f5 in FIG. 6. The last stage is, for example, the filter layer f5.

A filter coefficient updating device is, for example, a combination of the loss function deriving unit 261 and the filter coefficient updating unit 271 in FIG. 6. The deriving unit is, for example, a combination of the loss function deriving unit 261 and a part of the filter coefficient updating unit 271 performing processing of deriving a filter coefficient. The updating unit is a part of the filter coefficient updating unit 271 performing processing of updating a filter coefficient of each filter.

A difference from desired data of the output data is, for example, the above-described loss function. The function is, for example, the above-described loss function. A method of derivation by means of error back propagation is described herein. Computing a gradient relating to the filter coefficient is described herein. The demodulating device is, for example, the demodulating unit in FIG. 6.

The filter device is, for example, a combination of the filter layers f1 to f5, the loss function deriving unit 261, and the filter coefficient updating unit 271 in FIG. 6. The receiving device is, for example, the optical receiver 130 in FIG. 1 that includes the demodulating unit 134 in FIG. 6. The transmitting and receiving system is, for example, the optical communication system in FIG. 1 that includes the demodulating unit 134 in FIG. 6.

The computer is, for example, a computer that performs processing performed by the filter coefficient updating unit 271 in FIG. 6. The filter coefficient updating program is, for example, a program that causes the computer to execute processing performed by the filter coefficient updating unit 271 in FIG. 6.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

This application is based upon and claims the benefit of priority from Japanese patent application No. 2020-072420, filed on Apr. 14, 2020, the disclosure of which is incorporated herein in its entirety by reference.

### REFERENCE SIGNS LIST

100 Optical communication system
110 Optical transmitter
111 Encoding unit
112 LD
113 Optical modulator
120 Transmission path
130 Optical receiver
131 LD
132 Coherent receiver
133 ADC
134 Demodulating unit
135 Decoding unit
201 Wavelength dispersion compensation processing
202 Polarization fluctuation compensation processing
203 Carrier phase compensation processing
251 Rx skew compensation processing
253 Polarization fluctuation compensation processing
255 Tx skew compensation processing
261 Loss function deriving unit
271 Filter coefficient updating unit
271x Filter coefficient updating device
27 lax Deriving unit
271bx Updating unit
281, 282, 283, 284, 285 Gradient derivation
291, 292, 293 Coefficient derivation
f1, f2, f3, f4, f5 Filter layer

What is claimed is:

1. A filter coefficient updating device that updates a filter coefficient of a plurality of filters of a filter layer in which the plurality of filters are connected in a first plurality of stages with respect to received data, the filter coefficient updating device comprising:
a deriving circuit configured to derive a filter coefficient of each of the plurality of filters in one or a plurality of stages included in the first plurality of stages, by means of output data being output from a last stage of the first plurality of stages; and
an updating circuit configured to update each of the filter coefficients.

2. The filter coefficient updating device according to claim 1, wherein
the deriving circuit derives a filter coefficient of each of the plurality of filters, by means of a difference from desired data of the output data.

3. The filter coefficient updating device according to claim 2, wherein
the deriving circuit acquires the difference as a function.

4. The filter coefficient updating device according to claim 1, wherein
the filter layer includes either a widely linear filter or a strictly linear filter.

5. The filter coefficient updating device according to claim 1, wherein
the deriving circuit derives a filter coefficient of each of the plurality of filters in the one or the plurality of stages, by means of error back propagation.

6. The filter coefficient updating device according to claim 5, wherein
the deriving circuit derives the filter coefficient of each of the filter of the plurality of filters in the one or the plurality of stages, by computing a gradient relating to the filter coefficient by means of the error back propagation.

7. A filter device comprising the filter coefficient updating device according to claim 1 and the filter layer.

8. A demodulating device comprising the filter device according to claim 7 and demodulating the received data.

9. The demodulating device according to claim 8, wherein
the demodulation is performed by equalization processing on the received data.

10. The demodulating device according to claim 8, wherein
the received data are acquired from a quadrature amplitude modulated received signal.

11. The demodulating device according to claim 8, wherein
the received data are acquired from a received signal that has reached a receiver by transmitting through an optical fiber.

12. The demodulating device according to claim 11, wherein
the plurality of filters in a stage of the first plurality of stages are for compensating for a failure in the received data attributable to a distortion of the received signal due to a first cause, and the plurality of filters in another stage of the first plurality of stages are for compensating for a failure in the received data due to a second cause being a cause different from the first cause.

13. The demodulating device according to claim 12, wherein
the first cause and the second cause are any of a Tx skew being a time skew between an in-phase component and a quadrature component of the received signal generated in a transmitting source of the received signal, a wavelength dispersion generated by the transmission, a polarization state fluctuation and a polarization mode dispersion being generated by the transmission, a frequency offset and a phase offset between a carrier of a transmitting signal in the transmitting source of the received signal and local oscillator light of a receiver receiving the received signal, and an Rx skew being the time skew of the received signal generated on a receiving side of the received signal.

14. The demodulating device according to claim 13, wherein
the first cause includes at least any of the Tx skew, the wavelength dispersion, the polarization state fluctuation and the polarization mode dispersion, the frequency offset, and the phase offset, and the second cause is the Rx skew.

15. A receiving device comprising the demodulating device according to claim 9 and receiving the received data.

16. A transmitting and receiving system comprising the receiving device according to claim 15 and a transmitting device that transmits the received data to the receiving device.

17. A filter coefficient updating method of updating a filter coefficient of a plurality of filters of a filter layer in which the plurality of filters are connected in a first plurality of stages with respect to received data, the filter coefficient updating method comprising:
deriving a filter coefficient of each of the plurality of filters in one or a plurality of stages included in the first plurality of stages, by means of output data being output from a last stage of the first plurality of stages; and
updating each of the filter coefficients.

18. A recording medium on which a filter coefficient updating program causing a computer to execute processing of updating a filter coefficient of a plurality of filters of a filter layer in which the plurality of filters are connected in a first plurality of stages with respect to received data is recorded, the filter coefficient updating program causing a computer to execute:
processing of deriving a filter coefficient of each of the plurality of filters in one or a plurality of stages included in the first plurality of stages, by means of output data being output from a last stage of the first plurality of stages; and
processing of updating each of the filter coefficients.

19. The filter coefficient updating device according to claim 2, wherein
the filter layer includes either a widely linear filter or a strictly linear filter.

20. The filter coefficient updating device according to claim 2, wherein
the deriving circuit derives a filter coefficient of each of the plurality of filters in the one or the plurality of stages, by means of error back propagation.
